(19) United States
(12) Patent Application Publication
(10) Pub. No.: US 2015/0144883 A1
(43) Pub. Date: May 28, 2015

(54) FORMING RECESSED STRUCTURE WITH LIQUID-DEPOSITED SOLUTION

(71) Applicant: Atmel Corporation, San Jose, CA (US)

(72) Inventor: Bryan D. Sendelweck, Castle Rock, CO (US)

(73) Assignee: Atmel Corporation, San Jose, CA (US)

(21) Appl. No.: 14/087,859

(22) Filed: Nov. 22, 2013

(51) Int. Cl. H01L 29/06; H01L 21/02; H01L 21/311; H01L 29/16

(52) U.S. Cl. CPC H01L 29/0673; H01L 29/16; H01L 21/02527; H01L 21/02606; H01L 21/02628; H01L 21/31133
USPC 257/29; 438/497

(57) ABSTRACT

A damascene approach is used to form a recessed structure in a substrate for receiving liquid-deposited solution, such as a carbon nanotube (CNT) solution. The liquid-deposited solution is built-up in the recessed structure, simplifying the coating process and providing a more uniform thickness of the liquid-deposited layer.

### TECHNICAL FIELD

This disclosure relates generally to semiconductor processing.

### BACKGROUND

A conventional method of forming carbon nanotube structures for memory cells is to coat a wafer having a planarized surface with a carbon nanotube solution (liquid) using a spin coating process with a subsequent bake which results in a ˜25ang layer of carbon nanotubes. To achieve a useful thickness of carbon nanotubes, the wafer is coated and baked 20-30 times. The carbon nanotube film is subsequently patterned and etched to form structures in the film.

This technique is expensive because much of the carbon nanotube solution is wasted as it is spun off the wafer during the spin coating process. The number of repetitions of spin coating is time consuming, limits throughput and increases cost due to lower spin coating tool utilization. The repeated coat applications also result in a high defect level or density.

### SUMMARY

A damascene approach is used to form a recessed structure in a substrate for receiving liquid-deposited solution, such as a carbon nanotube (CNT) solution. The liquid-deposited solution is built-up in the recessed structure, simplifying the coating process and providing a more uniform thickness of the liquid-deposited layer.

Particular implementations of structure formation in liquid solutions using recessed structures provide one or more of the following advantages: 1) the recessed structure is formed with fewer processing steps; 2) at lower cost; and 3) with fewer defects than conventional methods that use a spin coating process.

### BRIEF DESCRIPTION OF THE DRAWINGS

FIGS. 1-5 are cross-sectional views illustrating a process for recessed structure formation using liquid-deposited solution.

FIG. 6 is a cross-sectional view of a memory cell including a liquid-deposited layer.

### DETAILED DESCRIPTION

### Example Processes

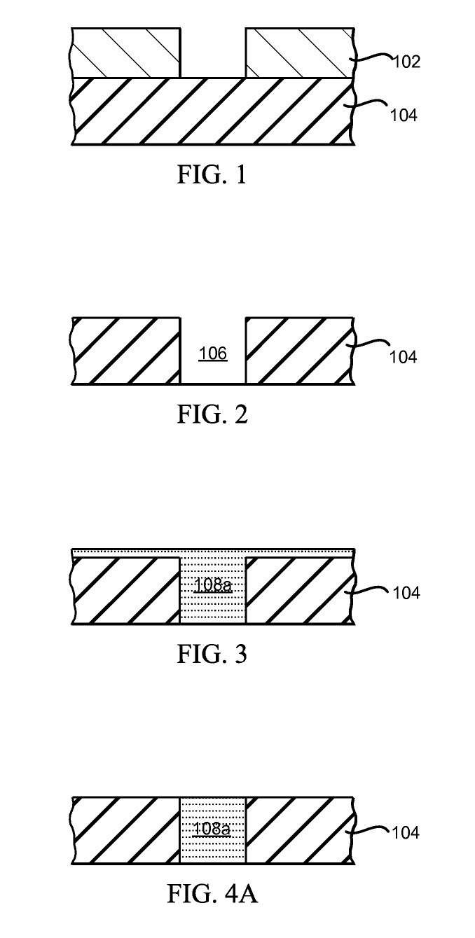

FIGS. 1-5 are cross-sectional views illustrating a process for recessed structure formation using liquid-deposited solution. Referring to FIG. 1, the process can begin by spin coating photoresist film 102 on dielectric substrate 104 (e.g., a wafer) and then patterning photoresist film 102 (e.g., using lithography) to define locations on substrate 104 for recessed structures. Substrate 104 can be, for example, an inter-layer dielectric (ILD). Substrate 104 is fully or partially etched and stripped according to the pattern in photoresist film 102, forming recessed structures 106 in substrate 104, as shown in FIG. 2. Only a single recessed structure is shown in the figures. In a practical implementation, however, a wafer substrate (e.g., silicon dioxide (SᵢO₂)) can include multiple recessed structures. Recessed structures 106 can be rectangular, circular or any other desired shape.

Next, liquid solution 108a is deposited on substrate 104 such that recessed structure 106 is filled with liquid solution 108a, as shown in FIG. 3. An example of liquid-deposited solution 108a is a carbon nanotube solution.

Substrate 104 is baked to form recessed plug 108b, where the numerical designation 108a designates a solution and the numerical designation 108b designates the recessed plug formed after baking solution 108a. In some implementations, portions of recessed plug 108b not in the recessed structure 106 are removed using a solvent or blanket etch, as shown in FIG. 4A.

Referring to FIG. 4B, in some implementations photoresist 102 is deposited on substrate 104, such that photoresist 102 is overlying recessed structure 106. Photoresist 102 is then etched and stripped leaving a portion of recessed plug 108b that overlies recessed structure 106. In some implementations, a portion of recessed plug 108b that remains after etching and stripping may “overhang” recessed structure 106, as shown in FIG. 5.

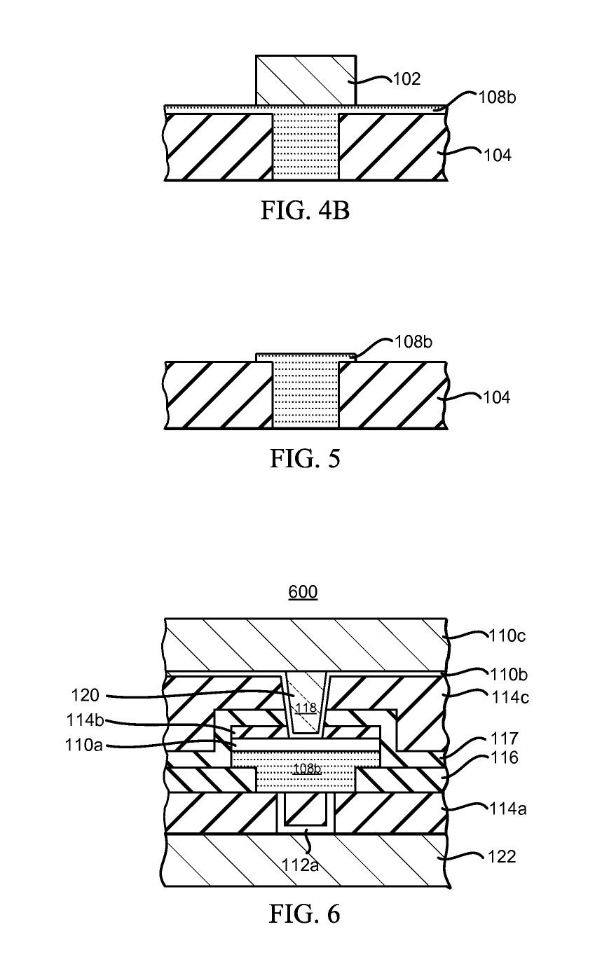

The semiconductor structure fabricated as described in reference to FIGS. 1-5 can be used to fabricate semiconductor devices, such as the memory cell described in reference to FIG. 6.

FIG. 6 is a cross-sectional view of an article of manufacture including recessed plug 108b fabricated according to the processes described in reference to FIGS. 1-5. In some implementations, the article of manufacture is memory cell 600, as described in the example below.

In some implementations, memory cell 600 includes first dielectric layer 114a (e.g., silicon dioxide (SᵢO₂)) over first metal layer 122 (e.g., AlCu). First dielectric layer 114a includes via/bottom electrode 112a (e.g., titanium nitride (TᵢN)). Recessed plug 108b (e.g., carbon nanotubes) is formed in dielectric well layer 116 (e.g., silicon nitride (S₃N₄)). Top electrode metal layer 110a (e.g., TᵢN) is formed on recessed plug 108b. Dielectric hard-mask layer 114b is formed on recessed plug 108b. Dielectric hard-mask layer 114b is formed with top cap 117 and second dielectric layer 114c. Second metal layer 110c (e.g., AlCu) is formed on second dielectric layer 114c and includes via 118 including metal liner 110b and via plug 120 (e.g., tungsten (W)).

Via liner/bottom electrode 112a is disposed in first dielectric 114a such that recessed plug 108b is electrically connected to first metal layer 122. Metal liner 110b is disposed in second dielectric 114c such that second metal layer 110c is electrically connected to top electrode metal layer 110a.

While this document contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can, in some cases, be excised from the combination, and the claimed combination may be directed to a sub combination or variation of a sub combination.

What is claimed is:

1. A method of fabricating an article of manufacture, comprising:
forming a recessed structure in a substrate;
depositing liquid solution on the substrate, filling the recessed structure; and
baking the substrate to form a recessed plug in the recessed structure.

2. The method of claim 1, further comprising:
depositing a photoresist film on the substrate; and
etching and stripping the photoresist film to form the recessed structure.

3. The method of claim 1, further comprising:
removing a portion of the recessed plug that is outside the recessed structure.

4. The method of claim 1, where the liquid solution is a carbon nanotube solution.

5. The method of claim 1, where the recessed structure is a rectangular or circular hole.

6. An article of manufacture, comprising:
a dielectric substrate;
a recessed structure in the dielectric substrate; and
a plug of liquid-deposited solution in the recessed structure.

7. The article of manufacture of claim 6, where the liquid-deposited solution is a carbon nanotube solution.

8. The article of manufacture of claim 6, where the recessed structure is a rectangular or circular hole.

9. The article of manufacture of claim 6, where the article of manufacture is included in a memory cell.

10. An article of manufacture made by the following process:
forming a recessed structure in a substrate;
depositing liquid solution on the substrate, filling the recessed structure; and
baking the substrate to form a recessed plug in the recessed structure.

11. The article of manufacture of claim 10, where the process further comprises:
depositing a photoresist film on the substrate; and
etching and stripping the photoresist film to form the recessed structure.

12. The article of manufacture of claim 10, where the process further comprises:
removing a portion of the recessed plug that is outside the recessed structure.

13. The article of manufacture of claim 10, where the liquid-deposited solution is a carbon nanotube solution.

14. The article of manufacture of claim 10, where the recessed structure is a rectangular or circular hole.

15. The article of manufacture of claim 10, where the article of manufacture is included in a memory cell.
